(19) United States
(12) Patent Application Publication
(10) Pub. No.: US 2002/0160617 A1
(43) Pub. Date: Oct. 31, 2002

(54) Method of etching a dielectric layer

(76) Inventors: Yun Hsiu Chen, Hsinchu (TW); Hsin Yi Chang, Keelung (TW); Yu Ling Huang, Chiai (TW)

Correspondence Address: BIRCH STEWART KOLASCH & BIRCH, PO BOX 747, FALLS CHURCH, VA, 22040-0747, US

(21) Appl. No.: 09/947,347

(22) Filed: Sep. 7, 2001

(30) Foreign Application Priority Data
Apr. 26, 2001 (TW) 90109981

(51) Int. Cl. H01L 21/302; H01L 21/461

(52) U.S. Cl. 438/704; 438/712; 438/756

(57) ABSTRACT

A method of etching a dielectric layer employs steps of: providing a silicon substrate with a surface covered by the dielectric layer; polymer-rich plasma etching to remove part of the dielectric layer and form a polymer film on the exposed regions of the dielectric layer and the silicon substrate; performing an oxygen plasma treatment on the polymer film; and wet etching to completely remove the polymer film.

### BACKGROUND OF THE INVENTION

1. Field of the Invention

The present invention relates to an etch process and, more particularly, to a method of etching a dielectric layer to increase process reliability and decrease the damage caused by ion bombardment.

2. Description of the Related Art

In semiconductor processing, dry etching is an anisotropic etch process that uses plasma to generate ion bombardment to make the vertical etching rate much greater than the horizontal etching rate. Recently, for dry etching of silicon oxide, silicon nitride or ordinary dielectrics, fluorocarbon-containing plasma is mostly employed, wherein the fluorine atoms react with the silicon atoms in an etch reaction, and the carbon atoms react with the silicon atoms as a polymer reaction. That is, the plasma etch process is a combination of the etch and polymer reactions. Accordingly, by appropriately tuning the strength of the ion bombardment and the production of polymer, plasma etch process obtains a desired etching rate and selectivity. However, the ion bombardment is intense, damaging the deposited thin film and the silicon substrate. Especially as circuit integration increases and device size is reduced, the damage caused by the plasma etch process becomes more serious.

Seeking to solve this problem, polymer-rich plasma etching is provided to manufacture a spacer structure. As shown in FIG. 1A, using conventional deposition, photolithography and etch processes, a gate insulating layer 12 and a gate electrode layer 14 are successively patterned on a predetermined are of a silicon substrate 10. Then, a dielectric layer 16 of silicon oxide or silicon nitride is deposited on the entire surface of the silicon substrate 10 to cover the exposed regions of the gate insulating layer 12 and the gate electrode layer 14. Next, as shown in FIG. 2B, polymer-rich plasma etching, with a tendency toward polymer formation by reducing the fluorine/carbon atom ratio, reduces the dielectric layer 16 positioned on the top of the gate electrode layer 14 and the surface of the silicon substrate 10, and deposits a polymer film 18 on the exposed surface of the gate electrode layer 16, the silicon substrate 10 and the remaining dielectric layer 16. Finally, the silicon substrate 10 is dipped into an etching solution, such as buffer oxide etcher (BOE) or dilute hydrofluoric acid (DHF), to wet etch the polymer film 18. Thereby, the dielectric layer 16 remaining on the sidewall of the gate electrode layer 14 is exposed and serves as the spacer structure.

In polymer-rich plasma etching, the deposition of the polymer film 18 decreases the ion-bombardment damage to the silicon substrate 10 and the dielectric layer 16 the process, thus ensuring reliability and electrical performance of the semiconductor device. However, the polymer film 18 of 150 Å˜200 Å is too thick to be completely etched away by ordinary etching solutions. In fact, part of the polymer film 18 remains on the silicon substrate 10 as shown in FIG. 1D. Although the polymer film 18 can be further removed by increasing the etching-solution concentration or prolonging the dipping time, there are still problems to be overcome, such as little control over the etching end-point, increased production costs, and increased production time. Thus, a novel method of etching a dielectric layer solving the aforementioned problems is called for.

### SUMMARY OF THE INVENTION

The present invention is a method of etching a dielectric layer with an extra oxygen plasma treatment to reduce the thickness of the polymer film, and thus ensure that the following wet etch process completely removes the polymer film.

The method of etching a dielectric layer has steps of: providing a silicon substrate with a surface covered by the dielectric layer; polymer-rich plasma etching to remove part of the dielectric layer and form a polymer film on the exposed regions of the dielectric layer and the silicon substrate; performing an oxygen plasma treatment on the polymer film; and wet etching to completely remove the polymer film.

Accordingly, it is a principal object of the invention to provide the oxygen plasma treatment to the polymer film before wet etching.

It is another object of the invention to provide the oxygen plasma treatment to reduce the thickness of the polymer film.

Yet another object of the invention is to provide the oxygen plasma treatment to loosen the exterior structure of the polymer film.

It is a further object of the invention to increase the reliability of etch end-point detection and decrease damage caused by ion bombardment.

Still another object of the invention is to ensure that wet etching completely removes the polymer film.

Another object of the invention is form a spacer structure.

It is an object of the invention to etch a barrier region of self-aligned silicide and manufacture an ONO structure of EPROM/EEPROM/FLASH device.

These and other objects of the present invention will become readily apparent upon further review of the following specification and drawings.

### BRIEF DESCRIPTION OF THE DRAWINGS

FIGS. 1A to 1D are sectional diagrams showing a method of etching a dielectric layer according to the prior art.

FIGS. 2A to 2E are sectional diagrams showing a method of etching a dielectric layer according to the present invention.

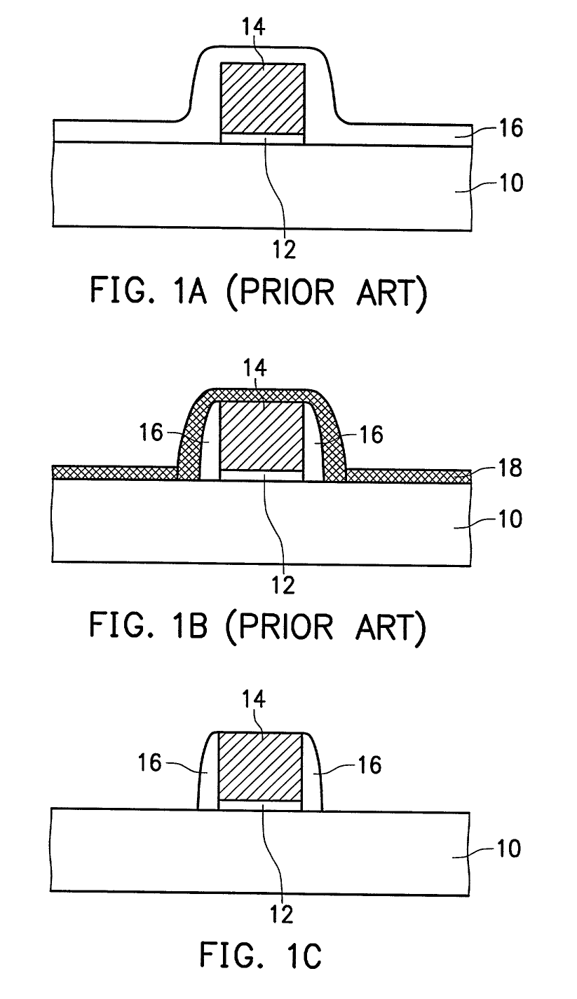

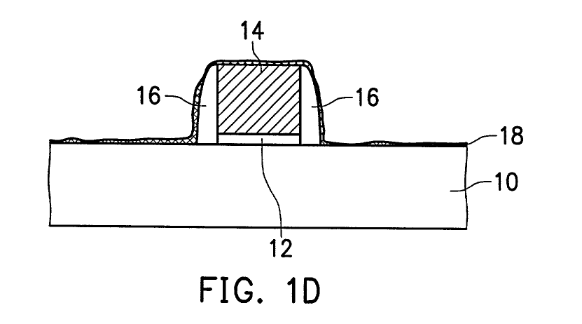

Similar reference characters denote corresponding features consistently throughout the attached drawings.

### DETAILED DESCRIPTION OF THE PREFERRED EMBODIMENTS

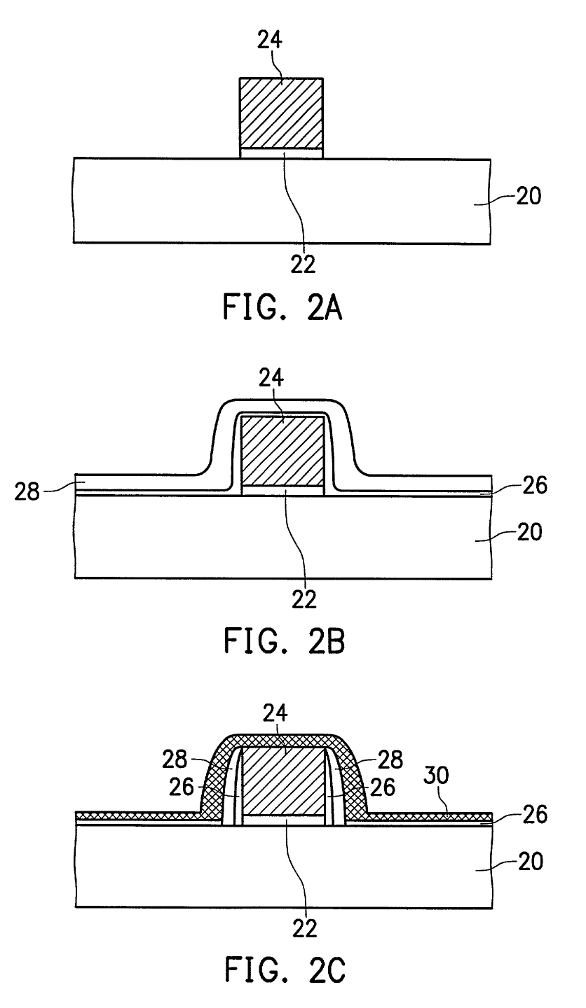

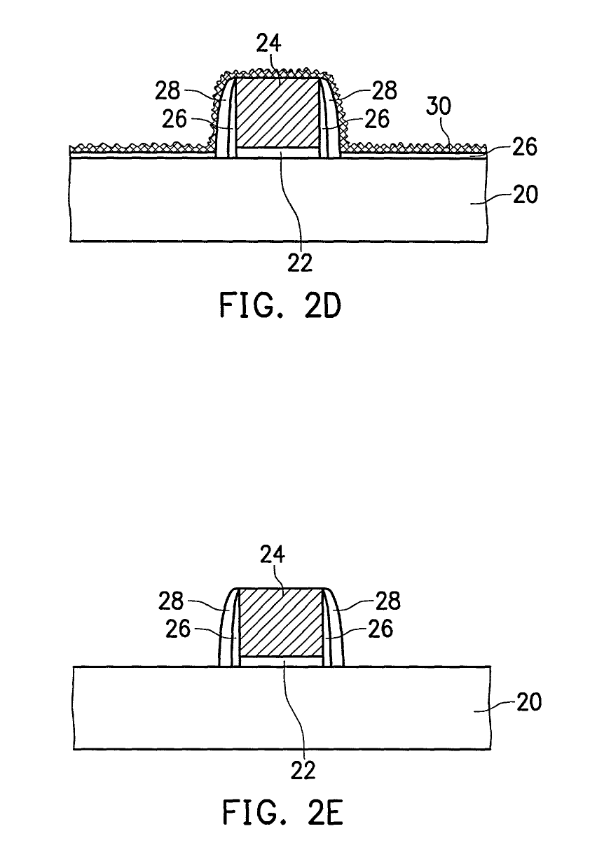

FIGS. 2A to 2E are sectional diagrams showing a method of etching a dielectric layer according to the present invention. As shown in FIG. 2A, using deposition, photolithography and etch processes, a gate insulating layer 22 and a gate electrode layer 24 are successively patterned on a predetermined area of a silicon substrate 20. Then, as shown in FIG. 2B, a first dielectric layer 26 of silicon oxide is deposited on the entire surface of the silicon substrate 20 to cover the exposed regions of the gate electrode layer 24, the gate insulating layer 22 and the silicon substrate 20. Next, a second dielectric layer 28 of silicon nitride is deposited on the entire surface of the first dielectric layer 26.

As shown in FIG. 2C, using polymer-rich plasma etching, when the second dielectric layer 28, the first dielectric layer 26 positioned on the top of the gate electrode layer 24, and the second dielectric layer 28 positioned over the surface of the silicon substrate 20 are all removed, a polymer film 30 of 150 Å˜200 Å is formed on the entire surface of the first dielectric layer 26 remaining on the silicon substrate 20, the second dielectric layer 28 remaining on the sidewall of the gate electrode layer 24, and the top of the gat electrode layer 24. Preferably, in controlling polymer-rich plasma etching, the approximately 60˜70 mt voltage is high, the operating power requirements are low, the major reactive gas consists of CH₃F and O₂, and the CH₃F/O₂ ratio and etching time are modulated to promote a tendency toward the polymer reaction.

As shown in FIG. 2D, using an oxygen plasma treatment, the surface of the polymer film 30 is loosened. Preferably, in controlling the oxygen plasma treatment, the temperature is high at 250˜270° C., the operating power requirements are low, and the major reactive gas consists of O₂ and Ar. Finally, the silicon substrate 20 is dipped into an etching solution, such as buffer oxide etcher (BOE), to wet etch away the polymer film 30 and the first dielectric layer 26 remaining on the surface of the silicon substrate 20. As a result, the first dielectric layer 26 and the second dielectric layer 28 remaining on the sidewall of the gate electrode layer 24 serve as a spacer structure.

Compared with the etch method in the prior art, the present invention's, removal of the second dielectric layer 28 and the following oxygen plasma treatment to restructure the polymer film 30 increases the reliability of etch end-point detection and decreases damage caused by the ion bombardment. Also, this ensures that the following wet etch process completely removes the polymer film 30 and the first dielectric layer 26 remaining on the surface of the silicon substrate 20. Furthermore, the method of the present invention applied to the formation of the spacer structure can be used in the applications of etching a barrier region of self-aligned silicide and manufacturing an ONO structure of EPROM/EEPROM/FLASH devices.

It is to be understood that the present invention is not limited to the embodiments described above, but encompasses any and all embodiments within the scope of the following claims.

What is claimed is:

1. A method of etching a dielectric layer, comprising steps of:
providing a silicon substrate with a surface covered by the dielectric layer;
polymer-rich plasma etching to remove part of the dielectric layer and form a polymer film on the exposed regions of the dielectric layer and the silicon substrate;
performing an oxygen plasma treatment on the polymer film; and
wet etching to completely remove the polymer film.

2. The method according to claim 1, wherein the polymer-rich plasma etching uses CH₃F and O₂ as the reactive gases.

3. The method according to claim 1, wherein the oxygen plasma treatment uses O₂ and Ar as the reactive gases.

4. The method according to claim 1, wherein the oxygen plasma treatment is performed at 200° C.˜300° C.

5. The method according to claim 1, wherein the oxygen plasma treatment reduces the thickness of the polymer film.

6. The method according to claim 1, wherein during wet etching, the silicon substrate is dipped into a buffered oxide etcher (BOE).

7. The method according to claim 1, wherein the dielectric layer is selected from a group consisting of silicon oxide, silicon nitride and an ONO structure.

8. The method according to claim 1, wherein the silicon substrate comprises:
a gate insulating layer patterned on a predetermined surface of the silicon substrate;
a gate electrode layer patterned on the gate insulating layer; and
the dielectric layer deposited on the exposed regions of the gate electrode layer and the silicon substrate.

9. The method according to claim 8, wherein polymer-rich plasma etching removes the dielectric layer from the top of the gate electrode layer and part of the dielectric layer on the surface of the silicon substrate and leaves the dielectric layer on the sidewall of the gate electrode layer.

10. The method according to claim 9, wherein polymer-rich plasma etching forms the polymer film on the top of the gate electrode layer, the dielectric layer remaining on the sidewall of the gate electrode layer and the dielectric layer remaining on the surface of the silicon substrate.

11. The method according to claim 10, wherein wet etching completely removes
the dielectric layer remaining on the surface of the silicon substrate.
